(19) United States
(12) Patent Application Publication
(10) Pub. No.: US 2023/0291350 A1
(43) Pub. Date: Sep. 14, 2023

(54) SOLAR CELL MODULES WITH VERTICAL PHOTOVOLTAIC CELLS

(71) Applicant: Preston Gabriel Nelson, Mount Vernon, IL (US)

(72) Inventor: PRESTON GABRIEL NELSON, Mount Vernon, IL (US)

(21) Appl. No.: 18/118,959

(22) Filed: Mar. 8, 2023

Related U.S. Application Data
(60) Provisional application No. 63/372,383, filed on Mar. 8, 2022.

(51) Int. Cl. H02S 30/10; H01L 31/047; H02S 20/30; H02S 99/00

(52) U.S. Cl. CPC H02S 30/10; H01L 31/047; H02S 20/30; H02S 99/00

(57) ABSTRACT

A solar cell module is constructed of a plurality of photovoltaic cells that are supported on a support surface of a support structure with the cells positioned side-by-side. The side-by-side arrangements of the cells form a first photovoltaic layer with a first exterior surface and a second photovoltaic layer with a second exterior surface. The first exterior surface and the second exterior surface extend outwardly from the support surface and oppose each other with a void between the exterior surfaces. The void enables photons from sunlight to enter into the void and reflect between the first exterior surface and the second exterior surface producing energy from the plurality of photovoltaic cells.

### CROSS REFERENCE TO RELATED APPLICATIONS

This application hereby incorporates by reference, in its entirety, and claims the benefit of the filing date of U.S. provisional patent application Ser. No. 63/372,383, which was filed on Mar. 8, 2022.

### FIELD OF THE INVENTION

This disclosure pertains to the construction and functioning of solar cell modules having multiple vertically and horizontally oriented photovoltaic surfaces. More specifically, this disclosure pertains to solar cell modules constructed of photovoltaic cells supported at angled relative positions on a support structure. The photovoltaic cells are relatively positioned with voids therebetween where the exterior surfaces of the cells form multiple channels. The first and second photovoltaic surfaces oppose each other on opposite sides of the channels whereby sunlight incident into each channel is reflected and absorbed between the opposing photovoltaic surfaces.

### BACKGROUND

Historically, flat photovoltaic “solar” modules have been comprised of flat horizontal layers of light-absorbing materials. The light-absorbing materials lay in a plane parallel to the photovoltaic module's protective glass layer, and roughly perpendicular to the general direction of the light rays such as sunlight rays. This formatting represents practically the entire “solar” market, today, and most productive modules only convert around 30% of the contacting light's energy, while reflecting much of the rest.

These efficiencies near 30% are attained via cutting edge technologies and exotic metals which are financially viable in aerospace applications. The small-scale residential home market, and the larger commercial distribution-level solar farm market, both exclusively employ photovoltaic modules consisting of these flat planar layers of doped silicon. In use the flat silicon plane panels are positioned generally perpendicular to incident rays of light such as sunlight. The flat silicon plane panels are estimated to represent over 99% of all man-made photovoltaic energy applications because of their great affordability in comparison to all other technologies.

Prior inventions have sought increased production via altered external geometries, in order to capture and concentrate more rays of light. Examples are disclosed in U.S. Pat. No. 11,177,400 B1; Nov. 16, 2021; Welser et al.; CONCENTRATOR PHOTOVOLTAIC SUBASSEMBLY AND METHOD OF CONSTRUCTING THE SAME and U.S. Pat. No. 10,707,807 B2; Jul. 7, 2020; Jacques; PYRAMIDAL WALL SECTIONS.

Other inventions present various texturized geometries, and some modifications to a solar cell's surface. Those largely function to increase the surface area of light-absorbing materials by locating current-carrying traces only on the backside of a cell. Examples are disclosed in U.S. Pat. No. 11,177,407 B2; Nov. 16, 2021; Irie et al.; METHOD FOR MANUFACTURING SOLAR CELL, SOLAR CELL, AND SOLAR CELL MODULE; and U.S. Pat. No. 11,171,254 B2; Nov. 9, 2021; Eisenberg et al.; BIFACIAL PHOTOVOLTAIC CELL AND METHOD OF FABRICATION.

A flaw of current solar cell modules is their single expanse of flat solar cells that is typically oriented perpendicular to incident rays of light such as sunlight. This creates limited opportunity for photovoltaic conversion, before light is largely reflected away from the module.

### SUMMARY

The solar cell module of this disclosure is basically constructed of a plurality of photovoltaic cells that are secured to and supported on a support structure.

The support structure can be constructed of a variety of different materials having sufficient structural strength to support the plurality of photovoltaic cells. The support structure has a support service that is configured for receiving and supporting the plurality of photovoltaic cells secured on the support surface. The support surface has a lateral dimension and a longitudinal dimension, with the lateral dimension and the longitudinal dimension being mutually perpendicular.

The photovoltaic cells can be any type of photovoltaic cells. Each photovoltaic cell has a conventional construction comprised of a layer of photovoltaic material that forms an exterior surface of the cell. Bifacial photovoltaic cells may also be used. The plurality of photovoltaic cells are primarily positioned and supported on the support surface of the support structure in several side-by-side arrangements. Each side-by-side arrangement of the plurality of cells forms a photovoltaic layer on the support surface with the photovoltaic layer having an exterior surface. The current carrying traces of the cells are located on the opposite side of the photovoltaic layer exterior surface.

The plurality of photovoltaic cells supported on the support surface are also arranged with adjacent layers of side-by-side cells being at relative angular positions. A fundamental or basic arrangement of the photovoltaic cells forms a first layer with a first exterior surface extending outwardly from the support surface, and a second layer with a second exterior surface extending outwardly from the support surface. For example, the first exterior surface and the second exterior surface extend outwardly at right angles from the support surface. There is also a third layer with a third exterior surface extending over the support surface between the first layer exterior surface and the second layer exterior surface. For example, the third exterior surface extends over and parallel to the support surface and forms right angles with the first exterior surface and the second exterior surface. The first exterior surface, the second exterior surface and the third exterior surface are each substantially planar surfaces.

The first exterior surface is oriented at or defines a first angle relative to the support surface and relative to the lateral dimension of the support surface. The second exterior surface is oriented at or defines a second angle relative to the support surface and relative to the lateral dimension of the support surface. The first exterior surface and the second exterior surface extend longitudinally across the support surface and are parallel with the longitudinal dimension of the support surface.

The first angle and the second angle are supplementary angles. The angled orientations of the first exterior surface and the second exterior surface position the first exterior surface opposing the second exterior surface and the second exterior surface opposing the first exterior surface with a channel or void defined between the first and second exterior surfaces.

With the third exterior surface positioned between the first exterior surface and the second exterior surface, the first exterior surface extends outwardly from the third exterior surface and defines the first angle between the first exterior surface and the third exterior surface. Additionally, the second exterior surface extends outwardly from the third exterior surface and defines the second angle between the second exterior surface and the third exterior surface. As stated earlier, the first angle and the second angle are supplementary angles. The first exterior surface, the second exterior surface and the third exterior surface are each substantially planar surfaces.

In a further embodiment, the first exterior surface and the second exterior surface are adjacent to each other and there is no third exterior surface between the first exterior surface and the second exterior surface. The first exterior surface and the second exterior surface define an angle between the first exterior surface and the second exterior surface. In this embodiment the first exterior surface is also oriented at or defines a first angle relative to the support surface and relative to the lateral dimension of the support surface. The second exterior surface is oriented at or defines a second angle relative to the support surface and relative to the lateral dimension of the support surface. The first exterior surface and the second exterior surface extend longitudinally across the support surface and are parallel with the longitudinal dimension of the support surface.

In all of the embodiments, there is a protective panel that extends over the first exterior surface and the second exterior surface. The first exterior surface and the second exterior surface space the protective panel from the support surface and enclose a void between the first exterior surface and the second exterior surface and between the support surface and the protective panel. The protective panel is a transparent panel.

Sunlight first passes through glass and the outer encapsulant as it enters inside the photovoltaic module. Rather than then encountering one single expansive plane of photovoltaic cells that is perpendicular to the direction of the incoming light (off of which the majority of the light would bounce, reflecting outwards from and not utilized by the module), rays of light are divided between many layers of verticalized photovoltaic cells, which rise from the module's bottom to top, with their conductive metallic tracers. When cells are arranged at the extreme 90 degrees, two adjacent cells may share one backplane with conductive tracers. The channels or voids separating the sets of cells allow space for the light's permeation.

Every incident where a photon contacts a verticalized cell is a new opportunity for energy transmission and photovoltaic generation. The portion of energy not absorbed during a contact is reflected across the void and onto the opposing cell wall, offering another opportunity for photovoltaic generation.

Extra tall modules may accommodate vertically-stacked cells in order to create deeper channels for the light to further permeate and dispense its energy, and various cell levels may be specifically suited for the absorption of certain wavelengths of light.

The diffusive and diffractive nature of light means that its particles never really travel in a straight line, even when the sun is directly overhead. Photons entering the module ricochet between cells, transferring more energy with each bounce, and therefore compounding electrical generation.

At the bottom of the module, photons may encounter a final cellular base plane, perpendicular to their general direction, which absorbs another “bounce” of energy, before sending the photons back up the channel. This final (normally horizontal) plane may also serve to connect the vertical cells.

In addition to its photon-trapping function, the newly presented format offers a greater amount of light-absorbing surface area.

To optimally absorb the sun's rays at various times throughout the solar day, the verticalized cell rows may run about photovoltaic modules in various directions, with these modules being employed together in an array with microinverters.

Variation or modifications to the subject matter of this invention may occur to those skilled in the art upon review of the disclosure as provided herein. Such variations, if within the spirit of this invention, are intended to be encompassed within the scope of any claims to patent protection issuing upon this development.

### DESCRIPTION OF THE DRAWINGS

Further objects and features of the invention of this disclosure are set forth in the following description and in the drawing figures.

FIG. 1 is a schematic representation of a partial perspective view of the solar cell module of this disclosure.

FIG. 2 is a schematic representation of the entire solar cell module of FIG. 1.

FIG. 3 is a schematic representation of an end elevation view of the solar cell module of FIG. 1.

FIGS. 4a and 4b are schematic representations of the functioning of the solar cell module of FIG. 1.

FIG. 5 is a schematic representation of a perspective view of a variant embodiment of the solar cell module.

FIG. 6 is a schematic representation of an end elevation view of a further variant embodiment of the solar cell module.

FIGS. 7a-7e are schematic representations of various embodiments of the solar cell module.

FIG. 8 is a schematic representation of a pair of solar cell modules of this disclosure operatively connected in electrical communication.

### DETAILED DESCRIPTION

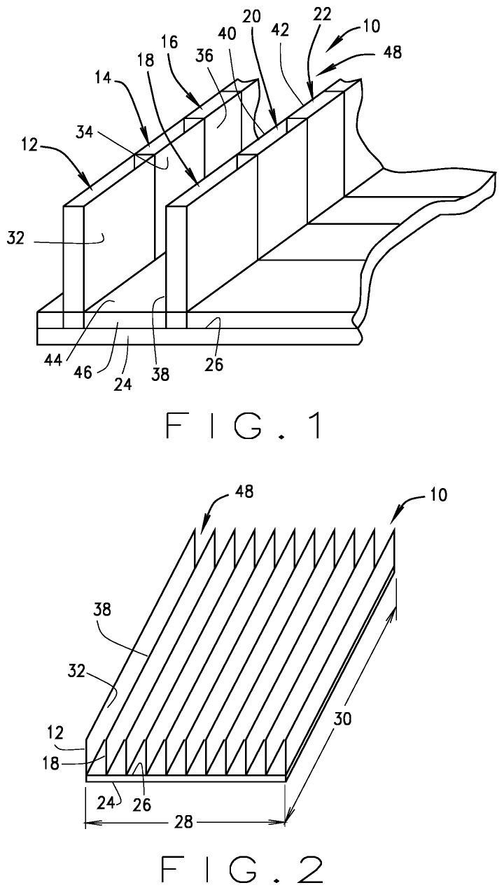

FIG. 1 is a schematic representation of a partial perspective view of the solar cell module 10 of this disclosure. FIG. 2 is a schematic representation of the complete solar cell module 10. The solar cell module 10 is basically constructed of a plurality of photovoltaic cells 12, 14, 16, 18, 20, 22 that are secured to and supported on a support structure 24. In the partial view represented in FIG. 1 there are only six photovoltaic cells 12, 14, 16, 18, 20, 22 represented. In the representation of the complete solar cell module of FIG. 2, the module 10 can be comprised of many more photovoltaic cells than the six represented in the partial view of FIG. 1.

The support structure 24 can be constructed of a variety of different materials that provide the solar cell module 10 with sufficient strength to support the plurality of photovoltaic cells that make up the solar cell module 10. As represented in FIG. 1 and FIG. 2, the support structure 24 has a support surface 26 that is configured for receiving and supporting the plurality of photovoltaic cells secured on the support structure 24. As represented in FIG. 2, the support structure 24 and the support surface 26 have a lateral dimension 28 that extends across the width of the solar cell module 10 from left to right as represented in FIG. 2, and a longitudinal dimension 30 that extends along the length of the solar cell module 10 from front to back as represented in FIG. 2. The lateral dimension 28 and the longitudinal dimension 30 are mutually perpendicular.

The photovoltaic cells 12, 14, 16, 18, 20, 22 can be any type of photovoltaic cell. Each photovoltaic cell has a conventional construction comprised of a layer of photovoltaic material that forms an exterior surface 32, 34, 36, 38, 40, 42 of each respective photovoltaic cell 12, 14, 16, 18, 20, 22. As represented in FIG. 2, the plurality of photovoltaic cells are primarily positioned and supported on the support surface 26 of the support structure 24 in several side-by-side arrangements that are laterally spaced from each other and extend longitudinally across the support surface 26. Each side by side arrangement of a plurality of cells forms a photovoltaic layer on the support surface with the photovoltaic layer having an exterior surface.

As represented in FIG. 1, the plurality of photovoltaic cells 12, 14, 16, 18, 20, 22 supported on the support surface 26 are arranged with adjacent layers of side-by-side cells being at relative angular positions. FIG. 1 is a representation of a fundamental or basic arrangement of the photovoltaic cells 12, 14, 16, 18, 20, 22 which forms a first layer having a first exterior surface 32, 34, 36 extending outwardly from the support surface 26, and a second layer with a second exterior surface 38, 40, 42 extending outwardly from the support surface 26. There is also a third layer with a third exterior surface 44 extending over the support surface 26 between the first layer exterior surface 32 and the second layer exterior surface 38. In the representation in the representation of FIG. 1, there are horizontally oriented photovoltaic cells positioned between the photovoltaic cells 12, 14, 16 and 18, 20, 22, although only one of the photovoltaic cells 46 with a third exterior surface 44 is visible in the representation of FIG. 1. In FIG. 1, the first exterior surface 32, the second exterior surface 38 and the third exterior surface 44 are each substantially planar surfaces.

The first exterior surface 32 is oriented at or defines a first angle relative to the support surface 26 and relative to the lateral dimension 28 of the support surface. As represented in FIG. 1, the first angle is a right angle or a 90-degree angle. The second exterior surface 38 is oriented at or defines a second angle relative to the support surface 26 and relative to the lateral dimension 28 of the support surface. As represented in FIG. 1, the second angle is a right angle or a 90-degree angle. The first exterior surface 32 and the second exterior surface 38 extend across the support surface 26 and are parallel with the longitudinal dimension 30 of the support surface as represented in FIG. 1 and FIG. 2.

The first angle and the second angle, both being 90 degree angles are supplementary angles. In other embodiments where the first angle and the second angle are not 90 degree angles, for example when the first photovoltaic cell 12 and its exterior surface 32 are positioned at a 30 degree angle relative to the support surface 26 and relative to the third exterior surface 44, the opposite second photovoltaic cell 18 and it's exterior surface 38 would be positioned at an angle of 150 degrees relative to the support surface 26 and relative to the third exterior surface 44. The supplementary angles maintain the parallel relationship between opposite photovoltaic cells 12, 18 and maintain the parallel relationship between the opposing exterior surfaces 32, 38 of the cells. By providing the opposing exterior surfaces 32, 38 of opposite photovoltaic cells with supplementary angles, the first exterior surface 32 of the first cell 12 opposes the second exterior surface 38 of the second cell 18 and the second exterior surface 38 opposes the first exterior surface 32 with a void or channel 48 defined between the first and second exterior surfaces.

As represented in FIG. 1, with the third exterior surface 44 positioned between the first exterior surface 32 and the second exterior surface 38, the first exterior surface 32 extends outwardly from the third exterior surface 44 and defines the first angle between the first exterior surface 32 and the third exterior surface 44. Additionally, the second exterior surface 38 extends outwardly from the third exterior surface 44 and defines the second angle between the second exterior surface 38 and the third exterior surface 44. As stated earlier, the first angle and the second angle are supplementary angles. The first exterior surface 32, the second exterior surface 38 and the third exterior surface 44 are each substantially planar surfaces.

As represented in FIG. 3, there is a protective panel 50 that extends over the first photovoltaic cell 12 and the second photovoltaic cell 18 and over the respective first exterior surface 32 and the second exterior surface 38. The first exterior surface 32 and the second exterior surface 38 space the protective panel 50 from the support surface 26 and from the third exterior surface 44. The protective panel 50 encloses the void 48 between the first exterior surface 32 and the second exterior surface 38 and between the third exterior surface 44 and the protective panel 50. The protective panel 50 is a transparent panel.

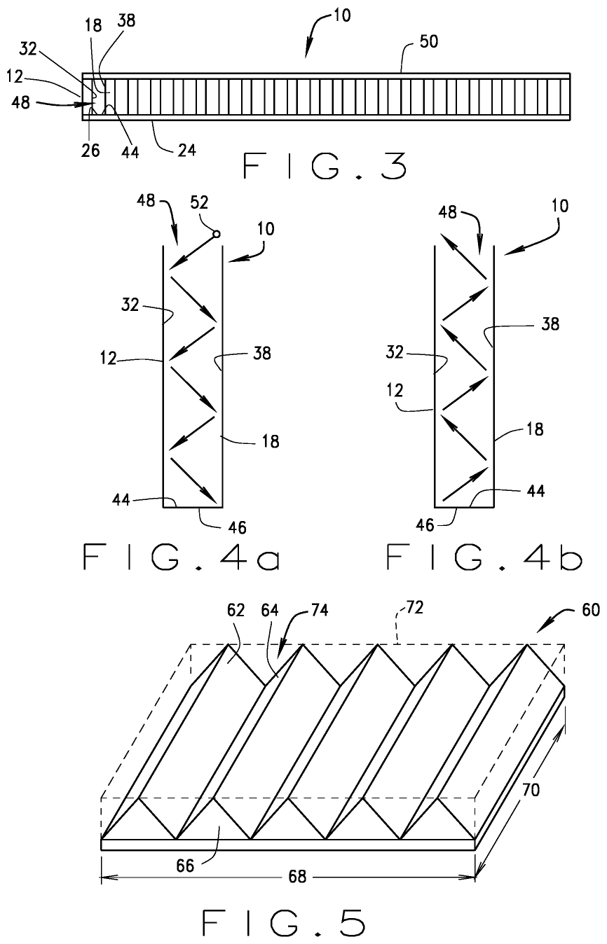

FIG. 4a and FIG. 4b provide representations of the functioning of the solar cell module 10. As represented in FIG. 4a, a photon 52 from sunlight enters the void or channel 48 between the exterior surface 32 of the first photovoltaic cell 12 and the exterior surface 38 of the second photovoltaic cell 18. The photon 52 contacts the first exterior surface 32 with a portion of its energy entering the first photovoltaic cell 12 and generating electricity. A portion of the energy of the photon 52 reflects off the first exterior surface 32 and is directed toward the second exterior surface 38 of the second photovoltaic cell 18. The photon 52 contacts the second exterior surface 38 with a portion of its energy being absorbed into the second photovoltaic cell 18 and generating electricity. Energy of the photon 52 not absorbed into the second photovoltaic cell 18 is reflected off the second exterior surface 38 and is directed back toward the first exterior surface 32. This process repeats as the photon 52 reflects downwardly between the first exterior surface 32 and the second exterior surface 38 until the photon contacts the third exterior surface 44. The contact of the photon 52 with the third exterior surface 44 results in a portion of the energy of the photon 52 being released into the horizontal photovoltaic cell 46. The photon 52 reflecting off the third exterior surface 44 then travels upward through the void or channel 48 reflecting off the second exterior surface 38 and the first exterior surface 32 with the remaining energy of the photon 52 being absorbed into the second photovoltaic cell 18 and the first photovoltaic cell 12, respectively. In the above manner, the solar cell module 10 of this disclosure operates more efficiently in extracting energy from a photon than conventional photovoltaic cells that have exterior surfaces positioned in a general perpendicular orientation relative to the path of photons received from sunlight.

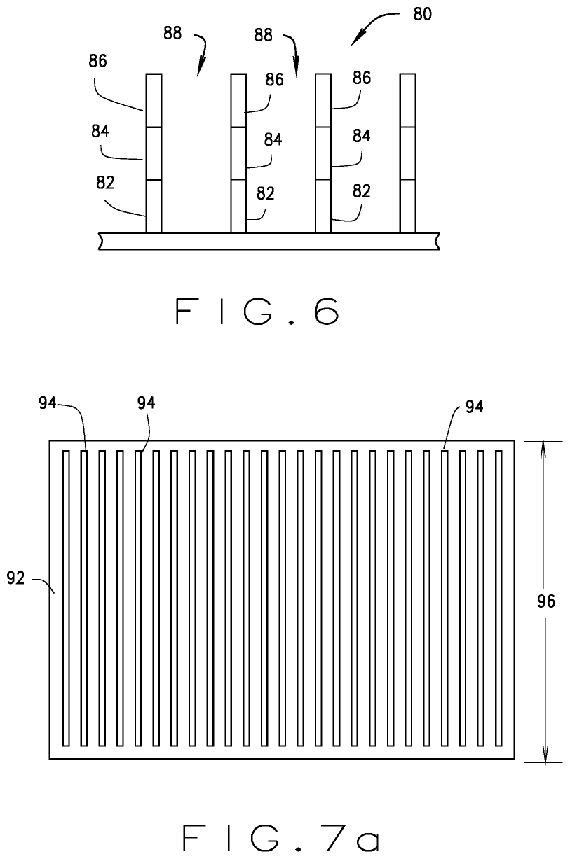

FIG. 5 is a schematic representation of a further embodiment of the solar cell module 60 of this disclosure. In the representation of FIG. 5, the first exterior surface 62 of a first photovoltaic cell and the second exterior surface 64 of a second photovoltaic cell are positioned adjacent each other, but there is no third exterior surface or third cell between the first exterior surface 62 and the second exterior surface 64. The first exterior surface 62 and the second exterior surface 64 define an angle between the first exterior surface 62 and the second exterior surface 64. In this embodiment the first exterior surface 62 is also oriented at or defines a first angle relative to the support surface 66 of a support structure and relative to a lateral dimension 68 of the support surface. The second exterior surface 64 is also oriented at or defines a second angle relative to the support surface 66 and the lateral dimension 68 of the support surface. The first exterior surface 62 and the second exterior surface 64 extend longitudinally across the support surface 66 and are parallel with the longitudinal dimension 70 of the support surface.

The embodiment of FIG. 5 functions in substantially the same manner as the earlier described embodiment of the solar cell module 10, with photons from sunlight directed between the first exterior surface 62 and the second exterior surface 64 and reflecting back and forth between the first exterior surface 62 and the second exterior surface 64.

Also in the embodiment of FIG. 5, there is a protective panel 72 that extends over the first exterior surface 62 and the second exterior surface 64. The protective panel 72 is represented by dashed lines in FIG. 5. The first exterior surface 62 and the second exterior surface 64 space the protective panel 72 from the support surface 66 and enclose a void or channel 74 between the first exterior surface 62 and the second exterior surface 64 and between the support surface 66 and the protective panel 72. In the embodiment of FIG. 5 the protective panel 72 is also a transparent panel.

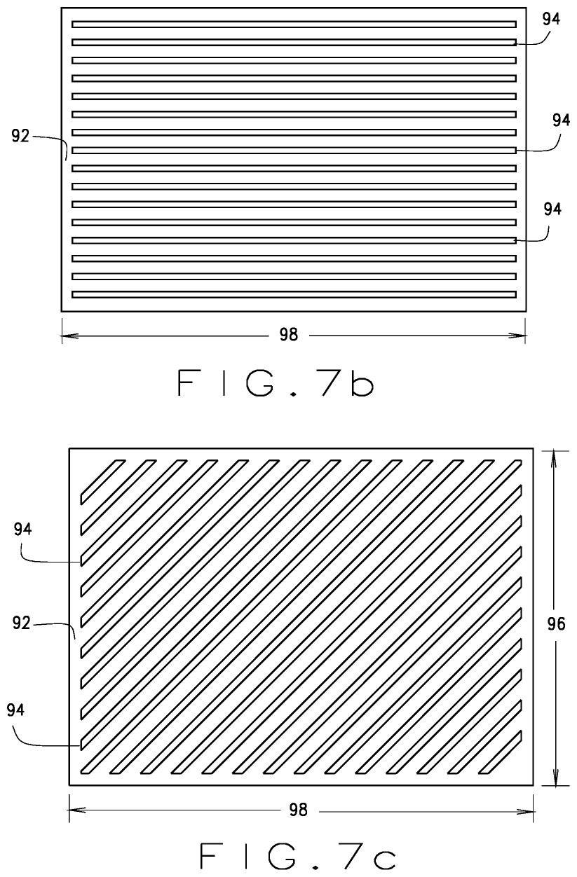

FIG. 6 is a representation of a variation of the solar cell module 80 of FIGS. 1 and 2. In FIG. 6 the solar cell module 80 is comprised of multiple photovoltaic cells 82, 84, 86 that are stacked end on end, creating deeper channels or deeper voids 88 between the cells 82, 84, 86. The deeper voids 88 enable photons from sunlight to further permeate and dispense their energy to the photovoltaic cells 82, 84, 86. In the embodiment of FIG. 6, the photovoltaic cells 82, 84, 86 could also have different levels of photo absorption or could absorb different wavelengths of light.

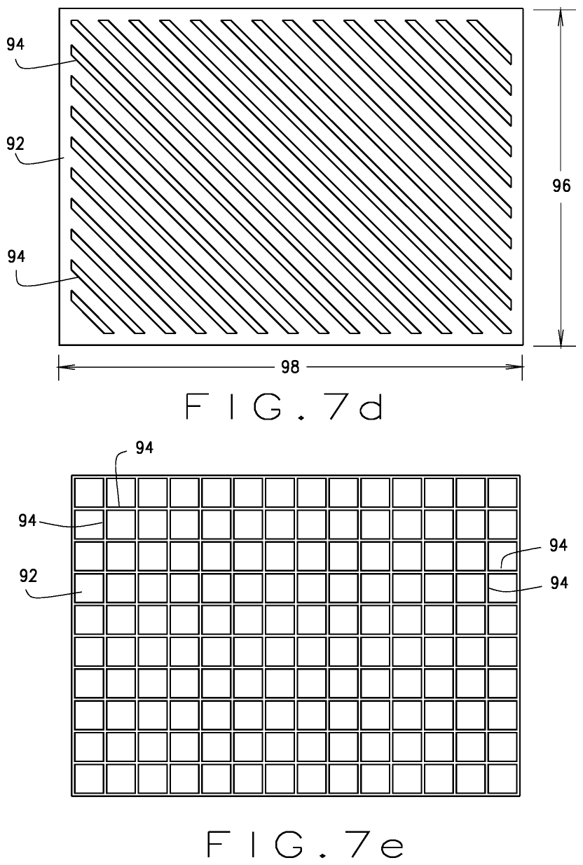

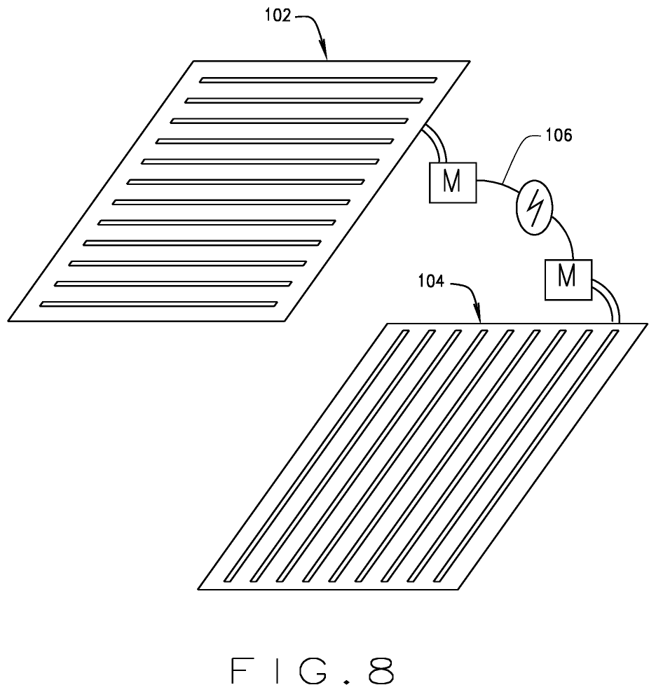

FIGS. 7a-7e represent various different possible arrangements of the photovoltaic cells on a support surface 92 of a support structure. As represented in FIG. 7a, the side-by-side arrangements of the photovoltaic cells 94 extend along the longitudinal dimension 96 of the support surface 92 just as in the embodiment described earlier with reference to FIG. 1 and FIG. 2. In FIG. 7b the photovoltaic cells 94 are arranged side by side along the lateral dimension 98 of the support surface 92. In FIGS. 7c and 7d the photovoltaic cells 94 are arranged side-by-side in diagonal orientations relative to the longitudinal dimension 96 and the lateral dimension 98. In FIG. 7e the photovoltaic cells 94 are arranged side by side in a crisscross pattern on the support surface 92.

FIG. 8 is a representation of the ability to connect various different configurations of the solar cell modules 102, 104 having different arrangements of photocells together in one electric circuit 106 taking advantage of multiple possible orientations of the photovoltaic cells to sunlight received at a particular geographic location.

Although the solar cell modules of this disclosure have been described with reference to several embodiments of the solar cells, it should be understood the above description is not intended to be limiting, and the scope of protection of the solar cell modules of this disclosure is defined only by the claims appended hereto.

1. A solar cell module comprising:
a support structure, the support structure having a support surface;
a first photovoltaic layer on the support surface, the first photovoltaic layer having a first exterior surface, the first exterior surface extending outwardly from the support surface;
a second photovoltaic layer on the support surface, the second photovoltaic layer having a second exterior surface, the second exterior surface extending outwardly from the support surface;
the first exterior surface opposing the second exterior surface; and
the second exterior surface opposing the first exterior surface.

2. The solar cell module of claim 1, further comprising:
the first exterior surface and the second exterior surface are each substantially planar surfaces.

3. The solar cell module of claim 2, further comprising:
a third photovoltaic layer on the support surface, the third photovoltaic layer having a third exterior surface, the third exterior surface extending outwardly from the support surface; and
the first exterior surface, the second exterior surface and the third exterior surface are each substantially planar surfaces.

4. The solar cell module of claim 2, further comprising:
the support surface having a lateral dimension and a longitudinal dimension, the lateral dimension and the longitudinal dimension being mutually perpendicular;
the first exterior surface being oriented at an angle relative to the lateral dimension of the support surface;
the second exterior surface being oriented at an angle relative to the lateral dimension of the support surface; and
the first exterior surface and the second exterior surface extending across the support surface parallel with the longitudinal dimension of the support surface.

5. The solar cell module of claim 2, further comprising:
the first exterior surface and the second exterior surface extending outwardly from the support surface define an angle between the first exterior surface and the second exterior surface.

6. The solar cell module of claim 1, further comprising:
a protective panel extending over the first exterior surface and the second exterior surface; and
the first exterior surface and the second exterior surface spacing the protective panel from the support surface.

7. The solar cell module of claim 6, further comprising:
the protective panel is a transparent panel.

8. The solar cell module of claim 1, further comprising:
a third photovoltaic layer on the support surface, the third photovoltaic layer having a third exterior surface, the third exterior surface extending over the support surface between the first exterior surface and the second exterior surface.

9. The solar cell module of claim 8, further comprising:
the first exterior surface extending outwardly from the support surface defines a first angle between the first exterior surface and the support surface; and
the second exterior surface extending outwardly from the support surface defines a second angle between the second exterior surface and the support surface.

10. The solar cell module of claim 9, further comprising:
the first angle and the second angle are supplementary angles.

11. The solar cell module of claim 8, further comprising:
the first exterior surface extending outwardly from the third exterior surface, the first exterior surface extending outwardly from the third exterior surface defines the first angle between the first exterior surface and the third exterior surface; and
the second exterior surface extending outwardly from the third exterior surface, the second exterior surface extending outwardly from the third exterior surface defines the second angle between the second exterior surface and the third exterior surface.

12. The solar cell module of claim 11, further comprising:
the first angle and the second angle are supplementary angles.

13. The solar cell module of claim 8, further comprising:
the first exterior surface, the second exterior surface and the third exterior surface are each substantially planar surfaces.

14. The solar cell module of claim 8, further comprising:
a protective panel extending over the first exterior surface, the second exterior surface and the third exterior surface; and
the first exterior surface and the second exterior surface spacing the protective panel from the third exterior surface.

15. The solar cell module of claim 14, further comprising:
the protective panel is a transparent panel.

16. The solar cell module of claim 8, further comprising:
a fourth photovoltaic layer on the base surface, the fourth photovoltaic layer having a fourth exterior surface, the fourth exterior surface extending outwardly from the support surface.

17. The solar cell module of claim 16, further comprising:
the first exterior surface, the second exterior surface, the third exterior surface and the fourth exterior surface being planar, parallel surfaces.

18. A solar cell module comprising:
a support structure, the support structure having a support surface, the support surface having a lateral dimension and the support surface having a longitudinal dimension, the lateral dimension and the longitudinal dimension being mutually perpendicular;
a first photovoltaic cell on the support surface, the first photovoltaic cell having a first exterior surface, the first exterior surface extending outwardly from the support surface and being oriented at an angle relative to the lateral dimension of the support surface and the first exterior surface extending across the support surface parallel with the longitudinal dimension of the support surface;
a second photovoltaic cell on the support surface, the second photovoltaic cell having a second exterior surface, the second exterior surface extending outwardly from the support surface and being oriented at an angle relative to the lateral dimension of the support surface and the second exterior surface extending across the support surface parallel with the longitudinal dimension of the support surface; and
the first exterior surface and the second exterior service opposing each other with a void between the first exterior surface and the second exterior surface.

19. The solar cell module of claim 18, further comprising:
the first photovoltaic cell and the second photovoltaic cell being supported on the support surface oriented at an angle defining an angle between the first exterior surface and the second exterior surface.

20. The solar cell module of claim 18, further comprising:
a third photovoltaic cell on the support surface, the third photovoltaic cell having a third exterior surface, the third exterior surface extending over the support surface between the first exterior surface and the second exterior surface.
